(19) United States
(12) Patent Application Publication
(10) Pub. No.: US 2005/0041459 A1
(43) Pub. Date: Feb. 24, 2005

(54) Interface for removable storage devices

(76) Inventor: Donald Wilson McDonald, Culross (GB)

Correspondence Address: Patent Administrator;Testa Hurwitz & Thibeault, High Street Tower, 125 High Street, Boston, MA, 02110, US

(21) Appl. No.: 10/482,595

(22) PCT Filed: Jun. 27, 2002
(86) PCT No.: PCT/GB02/02958

(30) Foreign Application Priority Data
Jun. 27, 2001 (GB) 0115675.1
Jun. 27, 2001 (GB) 0115684.3

(51) Int. Cl. G11C 11/00

(52) U.S. Cl. 365/154

(57) ABSTRACT

An interface module and method to provide interfacing of removable digital storage devices (DSDs) to a host system, the interface module having multiple interfaces for the connection of digital storage devices, e.g. Compact Flash (86), a host communication means including a processor (110) for providing a communication channels to transport data (12) and other signals (18) between the digital storage device and the host system and means including a processor (110) for presenting data held on a connected DSD to the host system. Data contained in a DSD is presented to the host system in a transparent manner, that is the data appears as part of a local file or drive hierarchy without the intervention of the user. The invention enables constantly connecting and disconnecting different types of DSD which follow different protocols, without invoking installation routines, system error conditions, or other procedures involving heavy software or time overheads.

The present invention relates to an apparatus and method for interfacing digital storage devices.

The advent of consumer digital devices has consequently created new types of digital media storage. Examples of such consumer digital devices include products such digital cameras, personal digital devices (PDAs) and digital audio players.

In the case of digital cameras and digital imaging there are several popular forms of data storage device common in use. The market has adopted a number of standard devices which include Compact Flash (CF), SmartMedia (SM), Sony Memory Stick (SMS), SecureDigital/Multimedia Card (SD/MMC) and various types of PCMCIA storage device including compact Type II magnetic drives. In addition, some cameras write directly to PC compatible media such as writable optical discs (CD-R, CD-RW) and magnetic “floppy” disks. Generally, solid-state memory devices have limited storage capacity, and are not intended as the ultimate means of image storage due to cost constraints. Systems which use CD-R or CD-RW disks, however, do provide a cost effective means of storing and retaining images long-term. In terms of market uptake, together CF and SM account for more than 80% of the digital camera systems on the market. Card capacities are increasing rapidly with capacities expected to range from the current standard of 16 MB (megabytes) to 256 MB and above.

Although user preferences vary, digital camera users generally capture a full card of images and upload these image files to another system for long-term storage and archiving. Typically a PC system is used as a storage device, whereby images are transferred to an internal storage drive, which is most commonly an industry-standard hard drive. For ultimate data archiving, the image files can be transferred to a secure data storage medium such as CD-R or CD-RW using a PC as the intermediate storage system. It is also to be expected that consumer devices will become available which will link directly to the camera via the data communications interface. This is most commonly Universal Serial Bus (USB) although PC compatible RS232 interfaces are still in use.

In addition to requiring file storage capabilities, end-users will ultimately require prints of their images. This can be achieved today by printing directly from a PC on one of the many types of colour printer available. Although print quality is generally acceptable with available consumer devices, none of them can match the low cost per print, quality of print and durability of conventional wet-film prints. Accordingly, although digital camera uptake in the consumer market is now exceeding conventional camera shipment, the ability of consumers to achieve the same level of performance as conventional film is reduced by the absence of any cost-effective means of producing high-quality images directly from the camera or from the internal storage device.

To address this issue, manufacturers of high quality photo-printing equipment are planning to deploy public-access systems for the upload and printing of digital images. Traditional wet film processing equipment will be superseded by fully digital print systems. Consumers will directly insert the physical storage device into the “photo terminal” where the system will read all files and display the images on a video display for selection, manipulation and printing via the installed digital print system. It is intended that such systems will take the form of transactional terminals/kiosks with touch-screen displays which will be designed for consumer/customer use within a traditional retail environment. As such, both the terminal and the means of interfacing to the physical media have to be designed for ease of use and be engineered for robustness against accidental or deliberate misuse.

In addition, it is an essential requirement that images are transferred from the storage device to the processing terminal within a short period of time to reduce customer waiting time at the terminal. Given the current capacity of solid state devices (4-256 MB) and the planned improvement from manufacturers, it is a key requirement of such applications that the transfer rate is above 1 Mbyte per second and ideally an order of magnitude higher.

Similarly, digital music players, which rely on compressed audio files, also use the same types of solid state memory devices and interfaces as are used in digital cameras, although at present, SD/MMC and SMS are the most common types used. For these, there exists an opportunity for retailers to offer digital music download within stores by writing directly to the physical storage device or by interfacing via one of the communication ports provided on the player (normally USB).

Again, some form of public access terminal will be required which customers can use directly without store assistance, and which will incorporate full transactional payment facilities. This application essentially parallels that of digital imaging with the difference being that data is written to the physical memory device, rather than read off it. The user interface may be more demanding for imaging applications than for audio. Otherwise, the requirements in terms of electronic communication and physical features of the read/write interface are the same in both applications.

Although there will be other applications and products which use compact forms of digital storage device, the rapid uptake of both digital cameras and digital audio players coupled with requirements for a range of versatile e-commerce transaction terminals, has created a need for some form of multi-device reader/writer, which can interface to all common types of storage device. The key features needed in such a device are multi-device handling capability, ease of use and robustness.

As not all products use the same memory device and it is necessary to cater for a range which should include CF, SM, SMS, SD/MMC and PC Card devices operating in true IDE mode.

Further, the reader should be designed to facilitate insertion and removal of the memory devices. It should be noted that some devices (particularly CF and PC Card) have a large number of connector pins and correspondingly high insertion/extraction force. Alignment of the device during insertion is critical. Ergonomics of the interface is important together with visual/audible feedback of correct insertion prior to each read/write cycle.

Although many types of reader/writer are available for PC use, these are generally not reliable/robust enough for public unattended use. The durability of the mechanical interface and components is key to the long term functionality of the device.

In addition to mechanical robustness, however, PCs are known to be prone to software “crashes”, and current operating systems, even with “plug and play” functionality cannot provide a reliable public access service. In particular, with the different media different error states can arise if media is not inserted correctly, is withdrawn prematurely, the data is corrupted, and so forth. Moreover, the diversity of physical and software interfaces from application programs to the devices themselves make it very difficult for manufacturers to implement a single kiosk apparatus compatible simultaneously with the wide variety of formats in the marketplace today.

It is an object of the present invention to provide a computer interface and application protocols which multiple digital media interface satisfying the criteria discussed above.

It is a further object of the present invention that the data contained in a storage device be presented to host system in a transparent manner, that is the data appears as part of a local file or drive hierarchy without the intervention of the user.

It is a yet further object of the present invention to enable interfacing of storage devices to a host system, constantly connecting and disconnecting different types of storage device which follow different protocols, without invoking installation routines, system error conditions, or other procedures involving heavy software or time overheads.

In a first aspect, the invention provides an interface module for the interfacing of removable digital storage devices (DSDs) to a host system, the module comprising:
a connector interface means for the connection of at least one digital storage device;
a host communication means for providing a communication channel to transport data and other signals between a digital storage device and the host system; and
a data presenter means for presenting data held on a connected DSD to the host system.

Preferably the connector interface means is adapted to read any data including low level data from the DSD.

Preferably the host communication means provides a first communication channel to transport data between a digital storage device and the host system and a second communication channel to transport control signals between the interface module and the host system.

Preferably the data presenter means further comprises a data buffer.

Preferably the data presenter means presents data held on a connected DSD to the host system as part of a file hierarchy local to the host.

Preferably the interface module further comprises a data routing means for routing of data and signals from a temporarily connected DSD to the host system.

Preferably the interface module further comprises a detection means for detecting connection of an DSD to the interface module.

Preferably, the detection means detects the DSD without reading data from the DSD.

Preferably the interface module further comprises a connection control means for controlling the physical connection of DSDs.

Preferably the interface module further comprises a user interface control means for controlling the user interface of DSDs.

Preferably the interface module further comprises an indication means for indicating the status of DSDs to the interface module.

Preferably the interface module further comprises flash memory for storing application firmware.

Hardware control functions for the plurality of different DSD receptacles may be integrated into a common control function within the interface module.

The data access functions and file system for the plurality of different DSD receptacles may be integrated into a single storage device driver within the host computer system.

Hardware control functions may be implemented via a separate driver.

This arrangement allows for the compact assembly of an interface module and associated module housing to receive a number of external connections. A single interfacing means is provided for a number of different digital media devices, providing high bandwidth communication channels with appropriate software control to present any one device in a transparent manner to a host system. This removes the inconvenience of separate detect and start-up routines at the application level, for when different types are connected, as would be the case in conventional arrangements.

The connector interface means may have a modular architecture wherein different communication and/or device protocols are catered for by different connector interface modules.

For example, it is possible to cater for several types of storage device via a single interface protocol. One example of this is to provide IDE interface logic for the interfacing of Compact Flash and PC-Card type II devices. Other examples using this modular approach include providing separate modules for handling the interfacing of USB compatible devices or wireless based devices. A wireless based device may operate according to the Bluetooth wireless standard or other known wireless protocols.

It is also possible to organise the interface modules or elements physically so as to facilitate ease of manufacture. An example of this would be to arrange the interface connections for memory stick, SD/MMC and SmartMedia devices onto a daughterboard PCB.

The interface connection to the digital storage devices may be implemented by using commercially available or proprietary components to physically interface to the communication channels of the of the interface module.

Said communication channels comprise interconnecting means arranged for high bandwidth transfer of data and other signal information between an externally connected DSDs and interface module.

The communication channels between an externally connected DSD and the interface module may be managed through the provision of proprietary interfaces and controllers.

For example, IDE interface logic may be provided to control the routing of data to the CPU from Compact Flash, PC-card Type II or other devices capable of operating in true ATE/IDE mode. Alternatively, a PCMCIA controller may be used for the case of Compact Flash and PC-card.

Similarly, data may be acquired from a device through a USB interface.

Preferably the interface module further comprises a bridging connector to provide data and signal management by the interface module for providing communication channels between an externally connected DSD and the interface module.

Said communication channels further comprise interconnecting means arranged to provide for high bandwidth transfer of data and other signal information between the interface module and host.

Said interconnecting means may comprise a suitable communications interface. The communications interface may comprise known standard interfaces.

Examples of standard interfaces which may be used to transfer data between the interface module and host system include IEEE 1394 (Firewire), small computer system interface (SCSI) and peripheral computer interface (PCI). The PCI solution may included both direct PCI and bridged PCI alternatives.

A PCMCIA controller may also be used to manage the flow of data to a host system.

Additionally, universal serial bus (USB) or derivative standard such as USB 2.0 may be used to transfer data to a host system.

Alternatively, IEEE 1394 may be used to transfer data to a host system.

An additional communication channel may be provided between the interface module and the host system in the form of a serial RS232 bus.

A separate input/output control block may be used to control the connection and disconnection of DSDs to the interface module.

This block may manage the direct control of any connection and disconnection indications for the DSDs, such as LED indicators. Similarly, this control may control any connection and disconnection mechanisms, for example, solenoids, for the opening and closing of shutter mechanisms to allow the connection or disconnection of DSDs to the connector interface means.

Behaviour of the I/O control block may be defined by application software executed on either the host system via the interface module or solely by the interface module.

This may be implemented using spare commands within the storage device interface (such as IDE). In the preferred embodiments to be described herein, however, the control block communicated with the host via the same physical interface, but with a distinct driver program. The I/O control is therefore implemented independently of the file system mapping, and a modular structure for the software and hardware can be maintained.

The control interface may be controlled by the same local CPU, or a dedicated MPU.

The GPIO block may be implemented as a single field programmable gate array (FPGA) or CPLD.

Management of the interface module behaviour is managed by the CPU. The CPU runs an embedded operating system (OS) capable of multitasking the read/write processes for each device and host data communications. This processor communicates with the host PC system via a number of communication ports.

Preferably the interface module further comprises an embedded OS that mediates interfacing of digital storage devices so as to present data stored on such a device as part of the host system local file/drive hierarchy wherein data stored on a DSD is mapped onto the file system of the host system and connecting or removing a device from the interface does not impact the normal operation of the host system.

The devices supported by the interface may include devices compatible with the following format types: Compact Flash, Smart Media, Sony Memory Stick, Secure Digital/Multimedia Card, or PCMCIA memory card (PC Card).

The external connections may provide inputs, outputs or both. In a digital media drive storage and retrieval application, the transport of data in the interface module will generally be inward, from the external connections to the processing module. In particular, external input connections may be provided by the interface module for the presentation of a flash file system, with high bandwidth interconnections provided in the interface module.

The operation of the interface module is unaffected by external DSD connection and disconnection.

The interface module may separately provide local bus interconnections for communication between other processing units.

The interface module may be subdivided into processing units, each unit receiving a set of separately pluggable externally connecting modules and processing the external signal.

The invention further provides a method for the interfacing of removable digital storage devices (DSDs) to a host system, the method comprising the steps:
connecting of at least one digital storage device;
providing a communication channel to transport data and other signals between said digital storage device and the host system; and
presenting data held on said connected DSD to the host system.

Preferably the step of providing a communication channel further comprises providing a first communication channel to transport data between a digital storage device and the host system and a second communication channel to transport control signals between the interface module and the host system.

Preferably the step of presenting data comprises presenting data held on a connected DSD to the host system as part of a file hierarchy local to the host.

Preferably the method further comprises routing of data and signals from a temporarily connected DSD to the host system.

Preferably the method further comprises detecting connection of an external DSD to the interface module.

Preferably the method further comprises detecting the DSD without reading data from the DSD.

Preferably the method further comprises controlling the physical connection of DSDs.

Preferably the method further comprises controlling the user interface of DSDs.

Preferably the method further comprises indicating the status of DSDs to the interface module.

Hardware control functions for the plurality of different DSD receptacles may be integrated into a common control function within the interface module.

Preferably the method further comprises accessing data for the plurality of different DSD receptacles by accessing a single storage device driver within the host computer system.

Preferably the method further comprises accessing hardware control functions for the plurality of different DSD receptacles by accessing a separate device driver within the host computer system.

In a second aspect the invention provides a method of and apparatus for interfacing removable digital storage devices to a host system wherein data held on said devices is presented transparently as part of the host system local file or drive hierarchy, wherein a driver stack interfaces said devices to the host system, the driver stack providing a mirror of the host system replicating commands and data across a driver stack.

In a third aspect the invention provides a method of and apparatus for interfacing a variety of removable digital storage devices (DSDs) to a host computer system wherein specific mechanical and electrical interfaces are provided for each type of DSD and data held on said devices is presented transparently as part of a host system file system, wherein a driver stack interfaces said different devices to the application level software in the host system via a common application programming interface.

Communication with the host computer system may present the various DSD types within a single storage class driver. For example, a standard SCSI type driver provides a superset of all the commands necessary to address and access files within the range of DSDs contemplated herein.

The devices may be assigned different logical drive names (drive letters) in the file system, and/or some of them may be integrated in a single logical drive.

### BRIEF DESCRIPTION OF THE DRAWINGS

Embodiments of the invention will now be described, by way of example only, with reference to the accompanying drawings, in which:

FIG. 1 shows a kiosk fascia including interface means for multiple digital storage devices in accordance with the present invention;

FIG. 2 is a system application diagram for the interfacing of said digital storage devices to a host system in accordance with an embodiment of the invention;

FIG. 3 is block diagram of an interface module with the embodiment of FIGS. 1 and 2;

FIG. 4 is a block diagram of the interface module for Within another embodiment of the invention;

FIG. 5 is a block diagram of yet another embodiment of the interface module;

FIG. 6 is a block diagram of yet another embodiment of the interface module;

FIG. 7 is a software component diagram for the embodiments of FIGS. 3, 4 or 6;

FIG. 8 illustrates a data communications stack within the embodiment of FIG. 7.

### DETAILED DESCRIPTION OF THE EMBODIMENTS

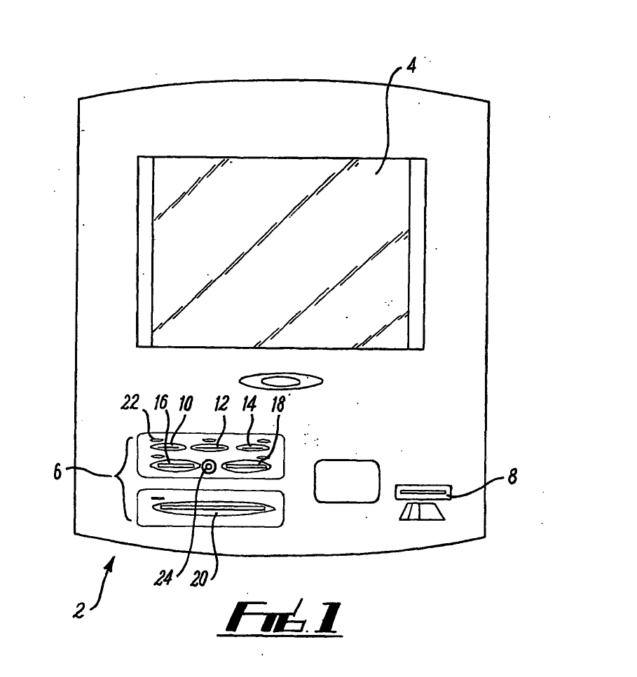

FIG. 1 shows a kiosk fascia including interface means for multiple digital storage devices.

This shows an embodiment of an electronic system for controlling a multi-device interface which has features which benefit embedded use within a kiosk 2 for the purpose of reading data from and writing data to physical solid state memory devices.

Such a kiosk 2 may for example comprise a screen 4 acting as a user interface. The screen may be implemented as a “touchscreen” to allow user interaction. Other means for user interaction may be provided, such as a keyboard or the like.

The kiosk provides a number of insert slots 6 for the insertion of different types of digital storage devices for interfacing to the kiosk host system. The host system controls the kiosk operation. Another slot is provided for insertion of credit cards of the like for charging of kiosk services.

The kiosk allows for a number of different digital storage devices to be used, providing separate slots for different devices such as, among others, Sony memory stick 10, SD/MMC 12, Smart media 14, compact flash 16 and PCMCIA Type II cards 18, as well as magnetic/optical media (CD-RW) 20.

The kiosk interface also provides indication means 22 for indicating if a device has been inserted, or, for example, if a device is in use by the kiosk or about to be ejected. For certain types of media such as compact flash or PCMCIA cards there is also provided means 24 for activating an insertion and ejection mechanism. Such a mechanism should provide the smooth transport of the device to and from the interface connecting means with the kiosk.

Memory Devices and Characteristics

Characteristics of memory device types and features can be summarised as follows:

Compact Flash

This is an open standard form of memory device originally developed by Sandisk Corporation. It is available in reasonably high capacities (currently up to 256 MB) and uses a parallel data communications bus. Internally the device uses flash memory components and can operate and store data in a true Flash File System (FFS) format. Compact flash includes an internal control device/ASIC which permits the device to be used in a so-called true ATA/IDE mode. This is accomplished by setting the control voltage one of the control pins on the 50 way interface connector. When activated in this mode, the device behaves exactly as an ATA/IDE device and through a direct interface, can be read from a PC systems IDE bus. Alternatively, the CF card can be interfaced to a PCMCIA port of a PC, with minimal passive re-routing of the signals form the CF card to the PCMCIA connector.

The architecture/bus design of this card permits a maximum burst data rate in true IDE mode of approximately 16 Mbytes per second. In true IDE mode, which is most commonly used in digital cameras, the FFS is mapped to an equivalent LBA (Logical Block Addressing) structure which can be read through the normal ATA command set.

The CF connector includes two pins which mechanically protrude beyond the others.

These are connected to ground and are used to interface to a card detect circuit to power the card only when the connector is inserted correctly. All CF cards are 5V TTL signal level power.

Smart Media

Details are not necessary for an understanding of the present invention.

Sony Memory Stick

Details are not necessary for an understanding of the present invention.

Secure Digital/Multimedia Card

Details are not necessary for an understanding of the present invention.

PCMCIA Memory Card (PC Card)

Details are not necessary for an understanding of the present invention.

Communications and Bandwidth

In order to interface all of the above devices and provide for future devices, it is necessary to specify a suitable form of communications interface which will allow data to be transferred between the host system (PC) and embedded system. A number of potential standard interfaces can be used for this product.

A well known interfacing standard is USB, a physical+protocol layer transmission standard introduced for general medium bandwidth communications for PC peripherals. The current standard and physical devices available is capable of a maximum serial bit rate of 12 Mbits/second. Given the serial nature of this transmission protocol and the requirements for handshaking and control, the maximum sustainable data transfer rate which can be achieved is of the order of 1 Mbyte per second. This would be adequate for current generation memory devices but would not provide sufficient bandwidth for memory capacities above 32 MB in this particular application. The primary advantages of this bus are simplicity, reduced development effort and low cost.

There is also the capability for supporting future iterations of the USB standard, such as USB2.0.

Examples of other standard interfaces which may also be used to transfer data between the interface module and host system include IEEE 1394 (Firewire), small computer system interface (SCSI) and peripheral computer interface (PCI). The PCI solution may include both direct PCI and bridged PCI alternatives.

A PCMCIA controller may also be used to manage the flow of data to a host system.

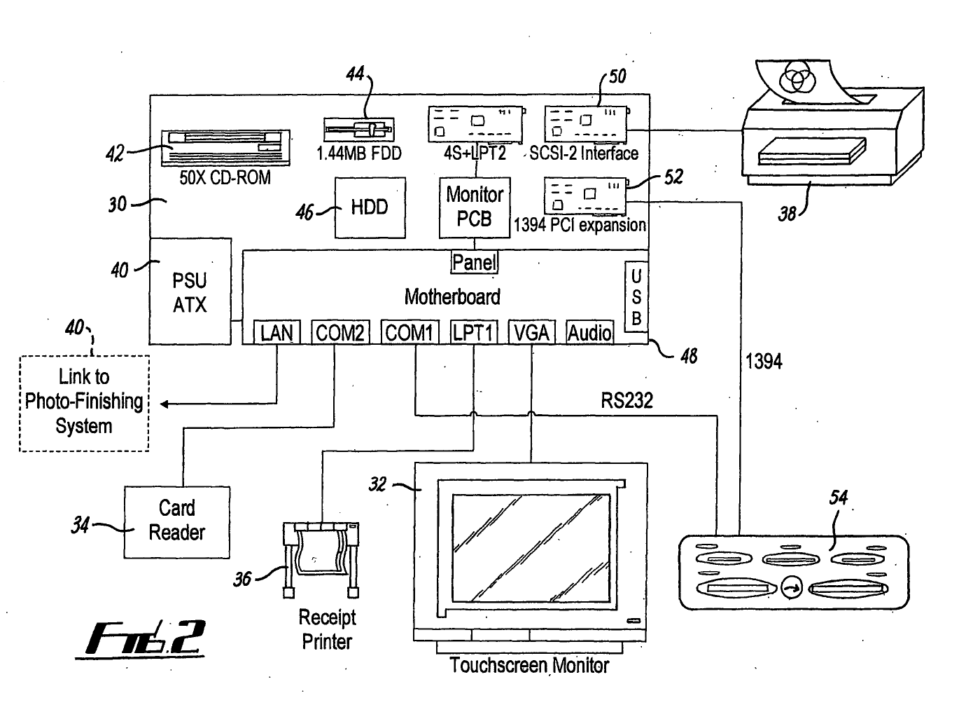

FIG. 2 is a system application diagram of an embodiment for interfacing digital storage devices to a host system.

This shows the main elements which make up the kiosk of FIG. 1, and other associated components.

The kiosk system comprises a host system 30, which is shown here implemented by a personal computer (PC) based system. A number of peripherals may be connected to the host system to provide the various functional aspects of the kiosk. A touchscreen monitor 32 provides a graphical user interface (GUI) for the kiosk. A card reader 34 is provided for reading credit cards or other type of charge card to provide payment for use of the kiosk, and a receipt printer 36 for proof of purchase. A colour printer may be provided for printing proof prints and other documents. Additionally, a link to photo-finishing system 40 is provided for the provision of high quality photographic prints. An interface module 42 provides the means for interfacing all of the key devices (such as CF, SM, SonyMS, SD/MMC and PCMCIA memory card) are in a single kiosk peripheral device, with the necessary controls features to suit applications in this area.

The host system comprises the necessary elements needed for interfacing and controlling the various peripherals of the kiosk, including media storage CD-ROM drive 42, floppy disk drive 44 and hard disk drive 46; motherboard 48, printer interface 50 and interface 52 to digital storage device interface module 54.

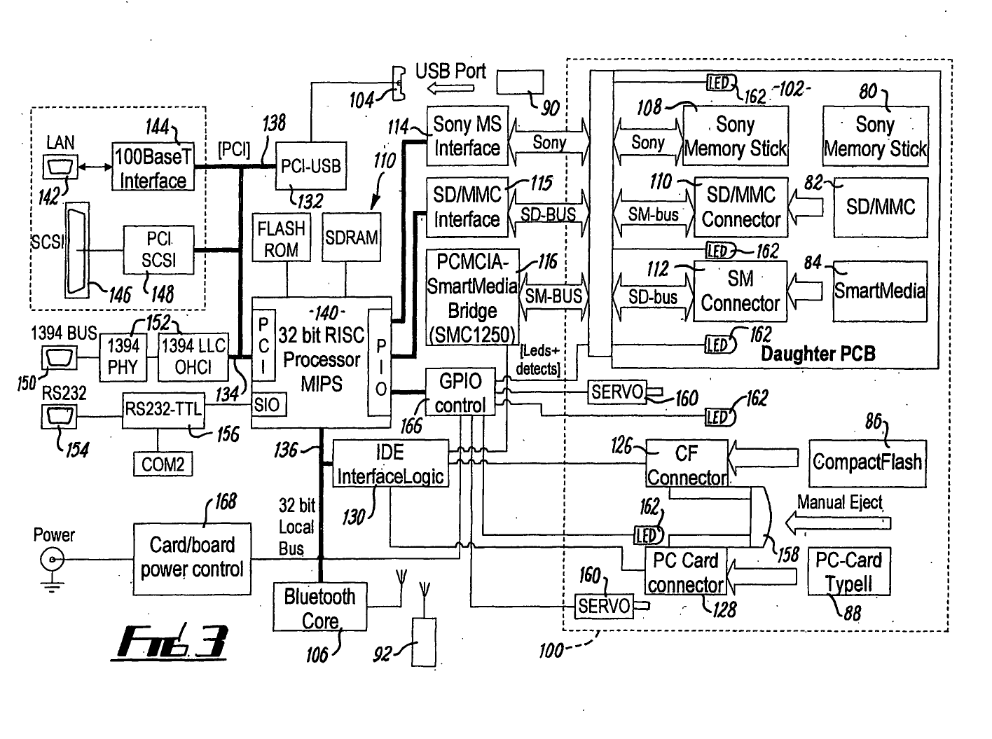

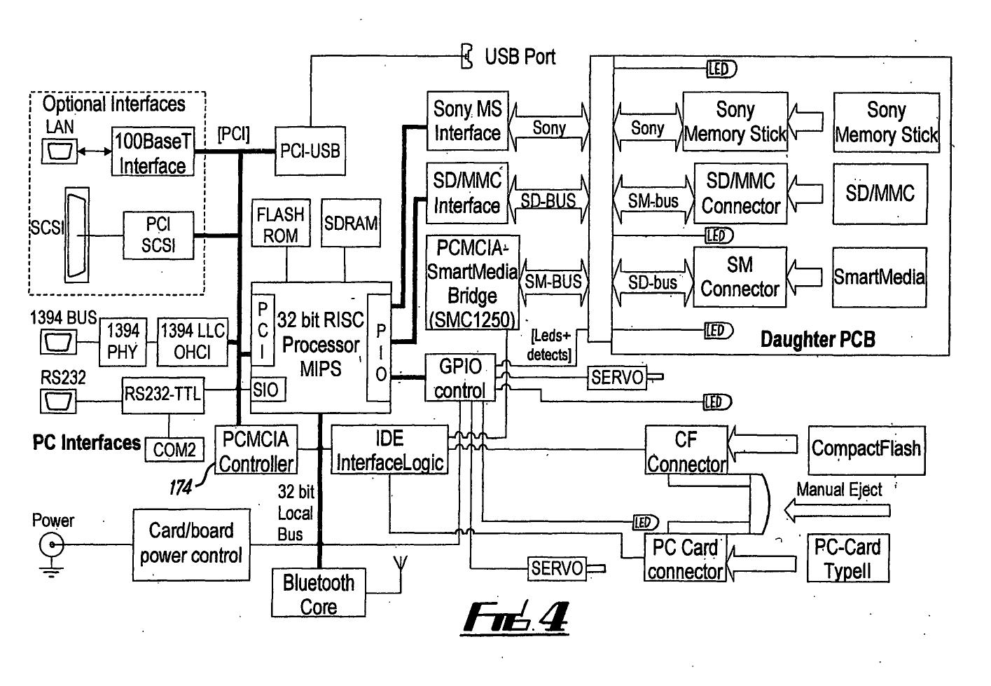

FIGS. 3 and 4 are block diagrams of two embodiments of the interface module of FIG. 2 and interfaces to the host system and other components.

FIG. 3 shows a basic embodiment of the electronic system of the interface module and FIG. 4 an embodiment with additional PCMCIA controller means. Like numerals describe like elements in each Figure.

Description of Electronic System

With reference to FIGS. 3 and 4 the electronic system of the interface module will now be described. The multi-device reader design is capable of read/write control of the following key devices:
Sony Memory Stick 80
Secure Digital/MMC 82
Smart Media 84
Compact Flash 86
PCMCIA card (PC card)—memory devices only in true ATA mode 88
Direct USB connection of device 90
Bluetooth wireless interconnection to devices 92

The system block diagram illustrates the electronic interconnection of components of a such a multi reader device. This includes a connector interface 100 to all of the above supported devices, 3 of which (SMS, SD/MMC and SM) are mounted on a daughter-board 102 to provide mechanical flexibility in the final assembly. This allows all of the market dominant memory storage devices to be accessed (read and write capability). In addition, two channels 104, 106 are provided for direct interfacing to digital products, i.e. USB 90 and Bluetooth 92.

The various devices 80-84 connect by way of connectors 108-112 to matching interfaces 114-116 and PCMCIA bridge 118 via buses 120-124. Similarly, devices 86, 88 are linked by way of connectors 126, 128 to IDE interface logic controller 130. PCMCIA bridge 118 also connects to IDE interface logic controller 130. Similarly, USB port connects to a PCI-USB bridge 132. Bus means 134-138 are provided for connection to a central processor unit 140.

Other ports include local area network (LAN) port 142 connecting to interface 144, small systems computer interface (SCSI) port 146 and interface 148, both connecting to bus 138.

There is also provided an IEEE 1394 (Firewire) port 150 and layers 152 connecting to bus 134 and an RS232 port 154 and layers 156 connecting to CPU 140.

A manual eject means 158 is provided for connectors 126, 128. Servo means 160 are further provided for physical transport of devices. Indicators 162 are provided for each connector means 108-112, 126, 128. Servo means 160 and indicators 162 are connected to general purpose input/output means (GPIO) 166. Card and power control 168 is also connected to GPIO 166. GPIO 166 is connected to CPU 140.

Also provided on the interface module are flash ROM 170 and SDRAM 172.

FIG. 4 shows an alternative embodiment of the electronic system with additional PCMCIA controller means 174. Like numerals describe like elements in FIGS. 3 and 4.

All devices are controlled by a 32 bit processor 140 which runs an embedded operating system capable of multitasking the read/write processes for each device and host data communications. This processor communicates with the host PC system via a number of communication ports. For data transfer (>1 Mbyte/sec), one of the high-bandwidth data ports is used, such as 1394 (“Firewire”) 150, 100Tx LAN 154 or SCSI 146. Only one data communications port will be implemented in any product, with the choice depending on the application and system integration requirements. Generally, 1394 will be the preferred communications channel. For slow speed data communication, a separate serial RS232 channel 154 is provided. This will enable boot loading of the 32 bit processor firmware from the host PC system. In addition, this communications channel can be used for low-level control commands to the device when the main data communications channel is unavailable. Such situations can occur when there is an operating system error on the host PC system which prevents communication over the main data channel which will invariably include a high level software protocol and operating system drivers and be somewhat prone to system hangs.

A number of additional external interface for future device support are also included, as will now be briefly described.

USB Port Interface:

In some situations, it may be desirable to connect to the physical device directly via a USB port 104, leaving the memory storage device intact in the product. For example, one potential application of the above device is delivering digital music to portable digital audio players e.g. MP3 players. Generally, these devices use USB as the data communications channel. The disadvantage of this approach is reduced data transfer rate due to the limitations of the USB interface (<1 Mbyte/sec average transfer speed). Although the device could be plugged directly into the Host PC's USB port, this may cause problems due to driver availability and system hangs from incorrect connection and removal of the USB device 90. It will also be necessary to provide Windows drivers for all types of devices supported, as many devices still do not implement a standard high-level protocol, but simply use the basic USB protocol to transfer data and commands.

Bluetooth:

Future products will use this emerging wireless standard, which is capable of burst data rates of typically 11 Mbits/sec and is comparable to USB performance. The clear advantage, however, is wireless connectivity. Suitable provision for an appropriate local bus bluetooth transceiver 106 will be provided as a plug-in.

Solid state memory storage devices generally operate on some from of true flash file system and can either employ a serial communications interface or a parallel interface (generally 8 bit). In addition, some devices, such as compact flash, can operate in a true IDE/ATA mode allowing them to be connected directly to a PC IDE expansion bus. Alternatively, it is possible to use a PCMCIA interface adapter, as this interface standard has ATA/IDE drivers as a subset, with only minor additional logic controls required to implement the ATA standard communication protocol. With the exception of CF and PCMCIA memory cards, all others use flash file systems, some of which are proprietary, e.g. Sony Memory stick. The following notes describe the communications and controls to each of the devices.

Compact Flash:

Compact flash can operate either in true flash file System (FFS) mode or true IDA/ATA mode. It is simpler to implement an ATA class driver than true FFS, so this device is controlled using ATA commands. The device is enabled in ATA mode by driving the appropriate pins on the interface connector. The ATA driver can either be coded directly for the embedded RTOS or it is possible to use any Card and Socket services (CSS) within the RTOS and to communicate via a PCI-PCMCIA bridge chip. This would replace the IDE interface logic block which is driven from the local bus of the processor. The disadvantage of utilizing a PCMCIA bridge could be speed, as the CSS incurs considerable protocol stack overhead.

Smart Media:

Smart media operates in a true FFS mode via an 8 bit data bus. To simplify the design and avoid the need to write detailed FFS drivers, this design uses a PCMCIA-smartmedia bridge ASIC (Feiya part number SMC1205DL). This ASIC maps the FFS to ATA commands and allows smart media to be connected to en ATA/IDE port. The ASIC takes care of all error checking required by the Smartmedia interface standards. NB It is important to cater for both 3.3V and 5C cards and ensure proper power on control sequence. This is handled by the card power control block.

Sony MS, SD/MMC

Both of these devices use a serial data/communications bus and require low level bitwise control from the processor. Some custom hardware may be required in each case to ensure proper signal levels control and timing.

ATA/IDE Block

As discussed above, CF, Smartmedia (via bridge chip) and memory type PC cards can all support the ATA command and data protocols. This is a relatively simple interface requiring minimal addressing. This block provides the necessary addressing and multiplexing of local bus lines to provide 3 selectable ATA interfaces. It is envisaged that this will be implemented within some form of FPGA/CPLD. Other digital control functions may also be swept into this block.

GPIO Block

The GPIO control logic block provides low level digital control of the front panel LED's and the shutter solenoids. Each device slot on the front bezel of the device has a single LED to indicate status to the end user of the device. For example, the LED will be illuminated when the user is prompted to insert the memory device. This user would be asked to identify the type of memory device they have, by application software controlling the images presented on the main kiosk screen. Additionally, the LED could be controlled in a pulsed mode to indicate when it is safe to remove the memory device from the slot. This is important, as loss of data or damage to the card could result from removal of the device whilst it is being accessed.

The control logic block also provides control of the two shutter solenoids on the CF and PCMCIA connector slots. This is ultimately controlled by the main application software. The shutters prevent users from inserting smaller cards into the larger CF and PCMCIA sockets. The control interface is connected to an external MCU which provides TTL level signals to the control logic circuit block.

All of the functionality of this block may be implemented together with the ATA interface within a single FPGA/CPLD.

1394 Bus

This bus is used as the preferred data communications channel for the device, giving a burst data rate of 400 Mbits/sec. Depending on the configuration and software stack, mean transfer rates in the 5-10 Mbytes/sec are possible. The choice of the Link Layer Controller (LLC) is particularly important in respect to speed. Most consumer type devices use a FIFO based controller due to cost requirements and such devices require a high processor overhead to control data transfer to and from the LLC. The particular LLC chosen for this design is a PCI based controller which allows burst data transfer of large data blocks via PCI command chaining: this gives a much higher transfer rate than local bus FIFO controllers.

In the design shown, the media drive operates as a client node on the 1394 bus, with a single port PHY device employed. In some situations, it may be a requirement for this device to act as a master on the 1394 bus and control other devices. Current and future consumer products may include 1394 interfaces (as present on digital video cameras) as the primary communications channel. As such it may be desirable to have an external 1394 port available as another direct consumer port. In this instance, a multi-port PHY device can be used in place of the single port PHY.

Processor and Associated IC's

The need for high bandwidth on the 1394 channel is the key requirements driving the selection of processor, which therefore requires a PCI expansion bus to drive the PCI LLC. Ideally, this processor should have integral PCI expansion, such as the Toshiba MIPS however, other processors with expansion companion chips such as the Intel SA110 would also be capable of powering this device. Overall, the performance is set primarily by the 1394 requirements, although the device needs to be able to simultaneously transfer data from the devices and to the host.

The main application code is stored within flash memory to permit in system programming (ISP) of the embedded application firmware. A suitable flash device will include a boot ROM section for storing non-volatile boot code. Application memory is available both internally on the processor and externally via a suitable SDRAM.

RS232

Serial RS232 is provided primarily as a low-level control channel and is used for command level control and diagnostics in the event of communications errors on the main data channel. In addition, application firmware will be flashed via this channel to provide a means of upgrading the embedded control software.

Power Control Block

Power is supplied via a single 3.5 mm jack plug to the power control block. This provides all of the necessary power to each component and control of the power on sequence to each device.

Alternative Implementations

There are a number of alternative approaches to providing a peripheral device capable of accessing all of the identified storage devices.

Using Commercially Available Single Readers

The interface module 54 can be implemented as a collection of single reader devices, such as are already commercially available, but with suitable adapter boards to present their slots in appropriate spatial relationship. Not all of the advantageous features highlighted in the present application can be implemented using these drives, however. In particular, the indicator LEDs, and status monitoring may not be available in such cases.

PCI Card

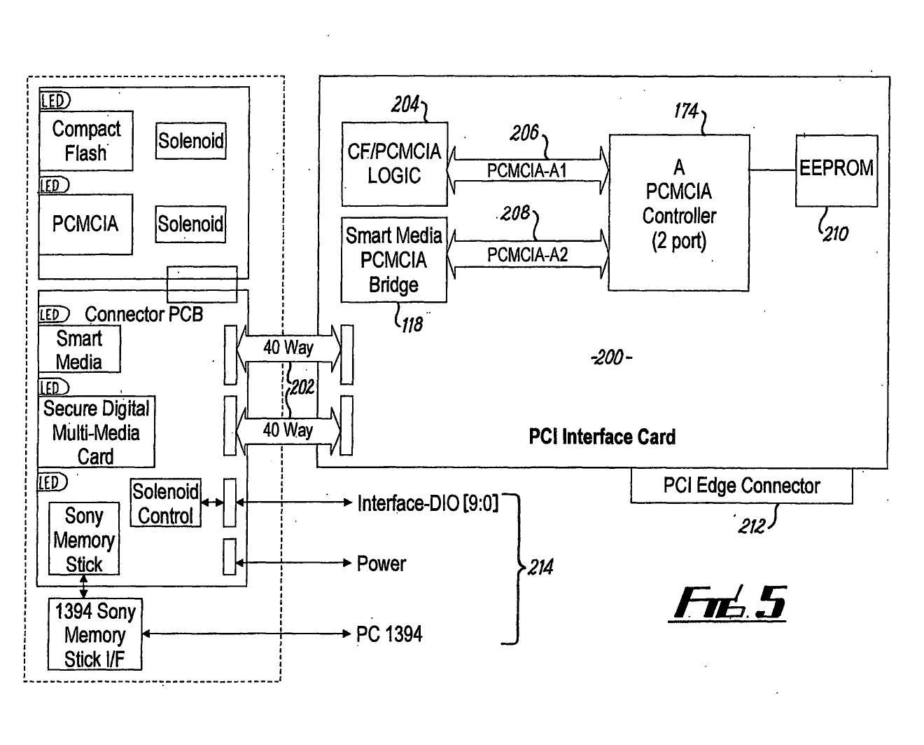

FIG. 5 shows a PCI implementation of the above described system.

The devices and their connectors are shown as before in FIGS. 3 and 4. These connect to a PCI connecting card 200 by way of buses 202. PCI card 200 holds the PCMCIA controller 174 with CF/PCMCIA logic 204 and SmartMedia PCMCIA bridge 118, connected by buses 206, 208 respectively. EEPROM 210 is also provided. Connection to the host system is by way of standard PCI edge connector 212. Other input/output routing is as shown at 214.

It is possible to eliminate the serial data communications channel by interfacing all devices onto a single integrated motherboard (PCI card) 200, as shown in FIG. 5. In this implementation, a PCI-local bus bridge is used, giving potentially 33 Mbytes/sec burst transfer speed across the host system's PCI bus (actual speed will depend on the chosen bridge IC). All of the devices will be interfaces via the PIO and ATA ports as described elsewhere. This approach gives the advantage of high data transfer from host to embedded controller.

However, the key disadvantage of this approach would be mechanical limitations, since the PCI bridge has to be in close proximity to the host processor/core logic, and the kiosk design has to be based around the single integrated motherboard

The advantage of adopting this approach may be minimal, as the communication with each device will become limited on the physical read/write limitation of each device. For instance, Sony MS is capable of a read data rate of 2 Mbytes/sec, so a direct PCI implementation does not provide any advantage. Even the fastest devices (CF and SM) are both only capable of a maximum data read of 16.6.Mbytes/sec in burst mode so the ideal channel bandwidth of around 10 Mbytes/sec (average) is required. This can be provided by 1394. The additional cost of the 1394 LLC and PHY is more than justified by the design flexibility this bestows. More importantly, a device based on 1394 is more easily integrated in a number of types of consumer facing kiosks where there may be some distance from the host system to the peripheral device.

1394—ATA Bridge

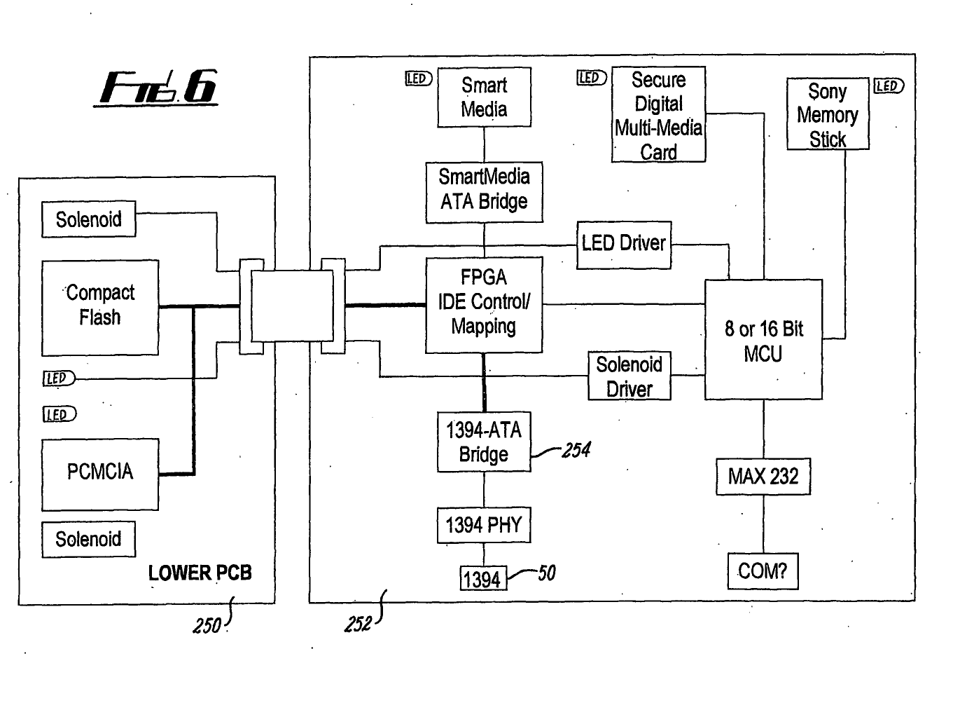

FIG. 6 shows a IEEE 1394 Firewire implementation of the system.

In this implementation A lower PCB 250 is connected to interface module 252 and host IEEE 1394 bus 50 by way of 1394—ATA bridge 254.

One of the difficulties of implementing the preferred device is developing the embedded 1394 protocol stack. This involves considerable low-level code and detailed knowledge of the 1394 bus standards and is generally regarded as a specialist area. One simple means of achieving a 1394 to ATA bridge (allowing all ATA devices to be controlled) is shown in FIG. 6. In this implementation, a single 1394-ATA bridge is used (e.g. Oxford semiconductor OX911) to interface the host 1394 bus to the ATA devices. Whilst in principle this appears to work and can be demonstrated to work, the practicalities of managing the devices preclude this as an option. For example, such devices generally use a higher level communications protocol, designated SBP2 (Serial Bus Protocol 2). This is implemented on Windows 2000 and is used specifically from removable media devices, normally based on 1394 physical bus. Windows 2000, which is the preferred kiosk operating system, will occasionally hang if the device is removed during a cycle or at any time. This is unacceptable in the case of a public access kiosk.

Other options are Host IDE Interface, SCSI and LVDS

Software Architecture

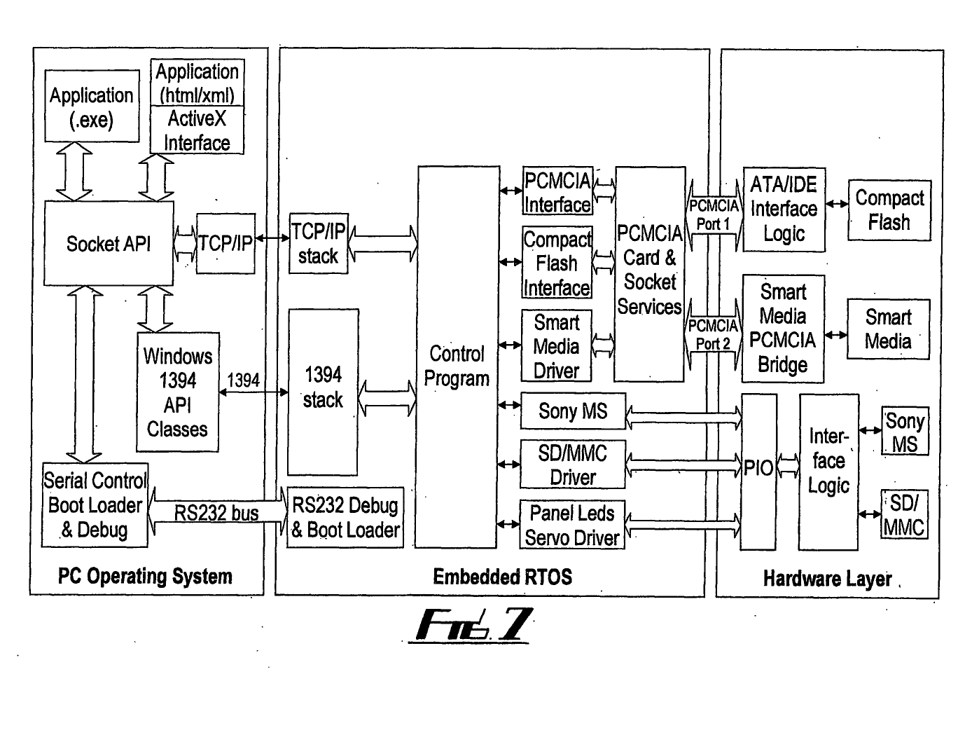

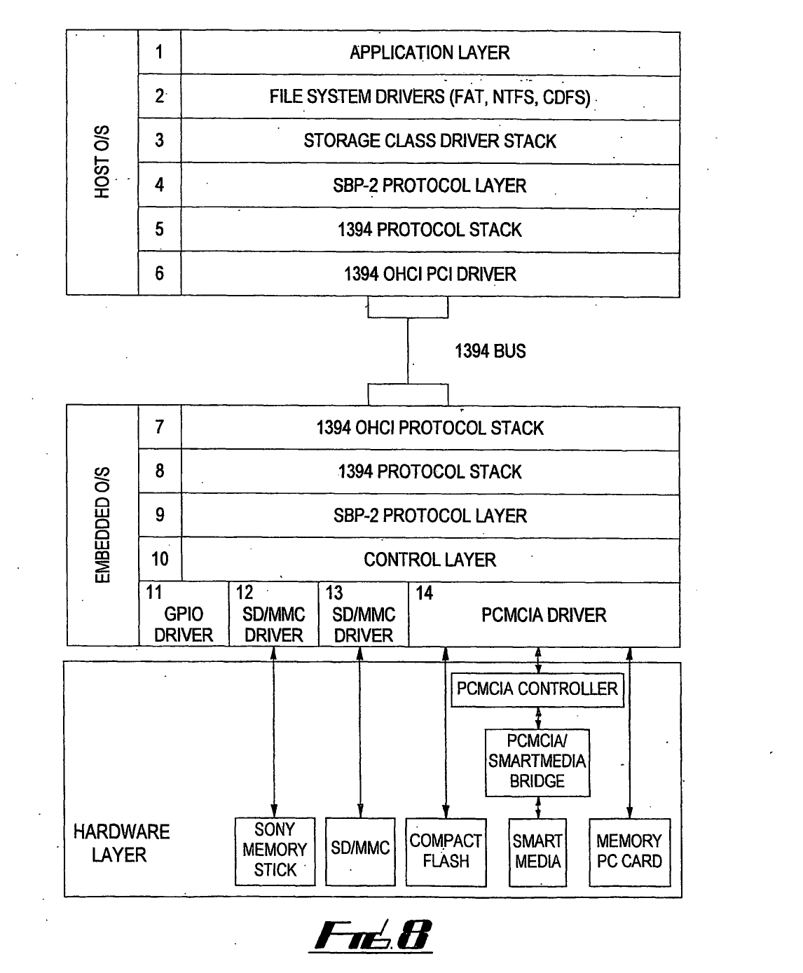

FIGS. 7 and 8 show details of the software systems, which are provided on both the host and client (embedded) side.

FIG. 7 shows the software component diagram, highlighting the functional elements of the host and client. The top level requirement is to make any of the removable storage devices visible to the application layer. This may be in the form of either a custom visual C++ application or alternatively web based html/xml/Java application running within a browser context.

1394 Device Driver Stack

FIG. 8 is a diagram of data communications driver stack for transparently interfacing digital storage device to a host system.

The ideal situation is to make the device visible through the device manager and provide a driver stack capable of interfacing to the file manager of the operating system. FIG. 8 shows the way this can be achieved on both the host and the client. This approach uses a generic transport protocol, termed SBP-2 (serial Bus Protocol) designed specifically for 1394 command and data transport. On the host side, this is shown as layer 4. The SBP2 protocol stack (4), communicates with 1394 protocol stack (5) to relay commands and data down to the 1394 controller. This diagram is simplified and, depending on the host O/S, there will be several intermediate layers within the driver stack. Nevertheless, the basic elements of the communications stack are illustrated correctly.

The embedded driver stack essentially mirrors that within the host. Thus, layers 4-9 provide a command and data transport mechanism which uses the physical 1394 serial bus. Above this layer, a storage class driver (3) delivers the device level commands to the stack. The most appropriate storage class to use is a SCSI based driver since all of the commands required are contained within the SCSI command set. The class driver then provides the link to the file management system (2) which can be based on a number of standard models, e.g. NTFS, DOS etc.

The device driver stack constructed in this way is therefore a block level stack i.e. levels 4-9 simply move/replicate commands and data by blocks across the 1394 bus and driver stack. Architecturally, this has advantages on both the client and host sides. On the client side, the control layer (10) is simply designed as if it were a SCSI device interface, receiving SCSI commands and executing them, such as data block read. On the host side, all components can be standard operating system components. One of the key requirements to construct this driver stack, is to provide full O/S plug and play (PnP) capability, so that when the physical device is plugged into the 1394 port, that the appropriate driver stack is enabled.

An important aspect of this design is the use of the OHCI (Open Host Controller Interface) PCI controllers for the 1394 link. This provides DMA capabilities not available on FIFO based controllers and gives major speed benefits on the embedded side.

Below the control layer in the embedded system, 3 of the devices (CF, SM and PCMCIA memory cards) will use a PCI based PCMCIA controller with the appropriate card and socket services stack (14). In this instance, the control layer simply translates the SCSI commands from the SBP2 layer onto the appropriate ATA commands to be executed by the PCMCIA driver (14). Since SCSI and ATA are very similar in structure, the resultant control layer is significantly simplified from the approach.

Both SD/MMC and Sony memory Stick require custom drivers to communicate commands and data over the serial bus to each device. To maintain consistency on the control layer interface, drivers 12 and 13 would be designed to interpret the same ATA command set as all other devices routed through the PCMCIA controller (14).

GPIO Control

Control of the low level logic devices including the LED's, solenoids and card detects can be accomplished through the serial control channel shown on Figure (5). Commands, such as turning on an LED, can be executed from the application utilizing a sockets-based command API. This block provides a hardware abstraction layer, buffering the application from the physical device drivers, presenting a simple string based message command syntax to the application developer. The block may comprise a buffer for storing a block-level or file-level representation of the device. This block uses standard “sockets” interfaces to establish communication between the application and custom device drivers.

It would be possible in alternative situations to embedded the hardware control signaling in the same logical channel as one of the drives, for example using spare commands in the IDE command set. The separation of the hardware control protocols from the media read/write channels simplifies greatly the implementation of the multi-medium interface unit and the application software also.

Boot Loader and Debug

The serial link between the host and the client systems also provide a means of downloading firmware revisions from the host. To enable this, the embedded system will include some form of non-volatile boot ROM to provide the basic utilities necessary to communicate with the host and receive new application firmware.

In addition, the serial channel will simplify the interfacing to the end application, as all of the peripheral devices used in the kiosk are controlled via the socket device driver. The high bandwidth data channel is used for data only and the serial link can therefore provide low level controls and diagnostics to overcome any problem occurring in the complex 1394 device driver stack.

Mechanical Details

As explained above, these are presented in a separate patent application.

### CONCLUSION

The apparatus and methods described enable the provision of a multi-interface terminal for public access applications in digital photography, digital audio and other applications. In addition to simple uploading and downloading of data, applications may provide for user data to be copied across from one storage device to another. The devices may be of different types, inserted simultaneously, or they may be inserted serially, with buffering provided either within the interface module or the host computer system.

The skilled person will appreciate from the foregoing the benefits and advantages of the invention in the various aspects highlighted in the introduction, and also in other aspects not specifically highlighted. A range of modifications and variations have been presented herein, and these and other modifications and variations may be contemplated without departing from the spirit and scope of the invention.

1) An interface module for the transparent interfacing of removable digital storage devices (DSDs) to a host system, the module comprising:
a connector interface means for the mounting and interconnection of at least one digital storage device;
a host communication means for providing a communication channel to transport data and other signals between a digital storage device and the host system; and
a data presenter means for presenting data held on a connected DSD to the host system.

2) The interface module of claim 1 wherein said connector interface means is adapted to read any data including low level data from the DSD.

3) The interface module of claim 1 wherein the host communication means provides a first communication channel to transport data between a digital storage device and the host system and a second communication channel to transport control signals between the interface module and the host system.

4) The interface module of claim 1 wherein the data presenter means further comprises a data buffer.

5) The interface module of claim 1 wherein the data presenter means presents data held on a connected DSD to the host system as part of a file hierarchy local to the host.

6) The interface module of claim 1 further comprising a data routing means for routing of data and signals from a temporarily connected DSD to the host system.

7) The interface module of claim 1 further comprising a detection means for detecting connection of an DSD to the interface module.

8) The interface module of claim 7 wherein the detection means detects the DSD without reading data from the DSD.

9) The interface module of claim 1 further comprising a connection control means for controlling the physical connection of DSDs.

10) The interface module of claim 1 further comprising a user interface control means for controlling the user interface of DSDs.

11) The interface module of claim 1 further comprising an indication means for indicating the status of DSDs to the interface module.

12) The interface module of claim 1 further comprising flash memory for storing application firmware.

13) The interface module of claim 1 wherein hardware control functions for the plurality of different DSD receptacles are integrated into a common control function within the interface module.

14) The interface module of claim 13 wherein the data access function and file system for said plurality of different DSD receptacles are integrated into a single storage device driver within the host computer system.

15) The interface module of claim 13 wherein hardware control functions are implemented via separate driver.

16) The interface module of claim 1 wherein said connector interface means has a modular architecture wherein different communication and/or device protocols are catered for by different connector interface modules.

17) The interface module of claim 1 wherein said communication channels comprise interconnection means arranged for high bandwidth transfer of data and other signal information between an externally connected DSDs and interface module.

18) The interface module of claim 1 wherein said communication channels between and externally connected DSD and the interface module are managed through the provision of proprietary interfaces and controllers.

19) The interface module of claim 1 further comprising a bridging connector to provide data and signal management by the interface module for providing communication channels between an externally connected DSD and the interface module.

20) The interface module of claim 1 wherein said communication channels further comprise interconnecting means arranged to provide for high bandwidth transfer of data and other signal information between the interface module and host.

21) The interface module of claim 1 wherein a PCMCIA controller is used to manage the flow of data to a host system.

22) The interface module of claim 1 wherein a universal serial bus (USB) is used to transfer data to a host system.

23) The interface module of claim 1 wherein IEEE 1394 is used to transfer data to a host system.

24) The interface module of claim 1 wherein an additional communication channel is provided between the interface module and the host system in the form of a serial RS232 bus.

25) The interface module of claim 1 wherein a separate input/output control block is used to control the connection and disconnection of DSDs to the interface module.

26) The interface module of claim 1 wherein the behavior of the I/O control block may be defined by application software executed on either the host system via the interface module or solely by the interface module.

27) The interface module of claim 1 further comprising an embedded OS that mediates interfacing of digital storage devices so as to present data stored on such a device as part of the host system local file/drive hierarchy wherein data stored on a DSD is mapped onto the file system of the host system and connecting or removing a device from the interface does not impact the normal operation of the host system.

28) The interface module of claim 1 wherein interface module is adapted to separately provide local bus interconnections for communication between other processing units.

29) The interface module of claim 1 wherein interface module is subdivided into processing units, each unit receiving a set of separately pluggable externally connecting modules and processing the external signal.

30) A method for the interfacing of removable digital storage devices (DSDs) to a host system, the method comprising the steps:
connecting of at least one digital storage device;
providing a communication channel to transport data and other signals between said digital storage device and the host system; and
presenting data held on said connected DSD to the host system.

31) The method of claim 30 wherein the step of providing a communication channel further comprises providing a first communication channel to transport data between a digital storage device and the host system and a second communication channel to transport control signals between the interface module and the host system.

32) The method of method claim 30 wherein the step of presenting data comprises presenting data held on a connected DSD to the host system as part of a file hierarchy local to the host.

33) The method of method claim 30 further comprising routing of data and signals from a temporarily connected DSD to the host system.

34) The method of method claim 30 further comprising detecting connection of an external DSD to the interface module.

35) The method of method claim 30 further comprising detecting the DSD without reading data from the DSD.

36) The method of method claim 30 further comprising controlling the physical connection of DSDs.

37) The method of method claim 30 further comprising controlling the user interface of DSDs.

38) The method of method claim 30 further comprising indicating the status of DSDs to the interface module.

39) The method of method claim 30 further comprising accessing hardware control functions for a plurality of different DSD receptacles using a common control function.

40) The method of method claim 30 further comprising accessing data for the plurality of different DSD receptacles by accessing a single storage device driver within the host computer system.

41) The method of method claim 30 further comprising accessing hardware control functions for the plurality of different DSD receptacles by accessing a separate device driver within the host computer system.

42) A method of and apparatus for interfacing removable digital storage devices to a host system wherein data held on said devices is presented transparently as part of the host system local file or drive hierarchy, wherein a driver stack interfaces said devices to the host system, the driver stack providing a mirror of the host system replicating commands and data across a driver stack.

43) A method of and apparatus for interfacing a variety of removable digital storage devices (DSDs) to a host computer system wherein specific mechanical and electrical interfaces are provided for each type of DSD and data held on said devices is presented transparently as part of a host system file system, wherein a driver stack interfaces said different devices to the application level software in the host system via a common application programming interface.
